(19) United States
(12) Patent Application Publication
(10) Pub. No.: US 2012/0025160 A1
(43) Pub. Date: Feb. 2, 2012

(54) NONVOLATILE MEMORY DEVICE

(75) Inventor: Takeshi Sonehara, Mie-ken (JP)

(73) Assignee: KABUSHIKI KAISHA TOSHIBA, Tokyo (JP)

(21) Appl. No.: 13/186,946

(22) Filed: Jul. 20, 2011

(30) Foreign Application Priority Data
Jul. 30, 2010 (JP) 2010-172723

(51) Int. Cl. H01L 45/00

(52) U.S. Cl. 257/2; 257/E45.001

(57) ABSTRACT

According to one embodiment, a nonvolatile memory device includes a stacked structure. The stacked structure includes a plurality of first interconnects, a plurality of second interconnects and a functional layer. The plurality of first interconnects extend in a first direction. The plurality of second interconnects are spaced from the first interconnects and extend in a second direction crossing the first direction. The functional layer is provided at each crossing position between the plurality of first interconnects and the plurality of second interconnects and has a transitioning function of transitioning between different resistance states and a rectifying function of rectifying current. The functional layer includes a metal layer, an opposed layer and a semiconductor layer. The semiconductor layer is provided between the metal layer and the opposed layer and is in contact with each of the metal layer and the opposed layer.

### CROSS-REFERENCE TO RELATED APPLICATIONS

This application is based upon and claims the benefit of priority from the prior Japanese Patent Application No. 2010-172723, filed on Jul. 30, 2010; the entire contents of which are incorporated herein by reference.

### FIELD

Embodiments described herein relate generally to a nonvolatile memory device.

### BACKGROUND

Recently, nonvolatile memory devices based on electrically re-programmable variable resistive elements have been drawing attention. As a device structure of nonvolatile memory devices, from the viewpoint of increasing the packing density, a three-dimensional cross-point structure is proposed. In the three-dimensional cross-point structure, a memory cell is located at the cross point of a WL (word line) and a BL (bit line).

In the three-dimensional cross-point structure, application of voltage to program data to a memory cell results in application of voltage to other non-selected memory cells. Thus, each memory cell needs to be provided with a diode (rectifying element) in conjunction with a resistance change film.

However, the memory cell and the rectifying element are stacked at the WL-BL cross point. While maintaining required characteristics, it is necessary to suppress the increase of the aspect ratio of the stacked structure to achieve processability improvement and characteristics uniformity.

### BRIEF DESCRIPTION OF THE DRAWINGS

FIG. 1 is a schematic view illustrating a nonvolatile memory device;

FIG. 2 is a schematic perspective view illustrating the cross-point structure;

FIG. 3 is a schematic sectional view illustrating the configuration of a memory cell;

FIGS. 4 to 7 are process sectional views illustrating a method for manufacturing a nonvolatile memory device;

FIGS. 8A and 8B are schematic sectional views illustrating the state transition of a functional layer;

FIGS. 9A and 9B are graphs illustrating the operation of the nonvolatile memory device;

FIGS. 10A and 10B illustrate the unipolar operation;

FIGS. 11A and 11B illustrate the bipolar operation;

FIGS. 12 to 19 are schematic sectional views illustrating examples of the functional layer;

FIGS. 20 and 21 are schematic perspective views illustrating a nonvolatile memory device;

FIG. 22 is a schematic perspective view illustrating the upper and lower functional layer; and

FIGS. 23A and 23B illustrate example combinations of the transition function and the rectifying function.

### DETAILED DESCRIPTION

In general, according to one embodiment, a nonvolatile memory device includes a stacked structure. The stacked structure includes a plurality of first interconnects, a plurality of second interconnects and a functional layer. The plurality of first interconnects extend in a first direction. The plurality of second interconnects are spaced from the first interconnects and extend in a second direction crossing the first direction. The functional layer is provided at each crossing position between the plurality of first interconnects and the plurality of second interconnects and has a transitioning function of transitioning between different resistance states and a rectifying function of rectifying current. The functional layer includes a metal layer, an opposed layer and a semiconductor layer. The semiconductor layer is provided between the metal layer and the opposed layer and is in contact with each of the metal layer and the opposed layer.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. The same portion may be shown with different dimensions or ratios depending on the figures.

In the specification and the drawings, components similar to those described previously with reference to earlier figures are labeled with like reference numerals, and the detailed description thereof is omitted as appropriate.

In the following description, by way of example, it is assumed that the first conductivity type is p-type and the second conductivity type is n-type.

### First Embodiment

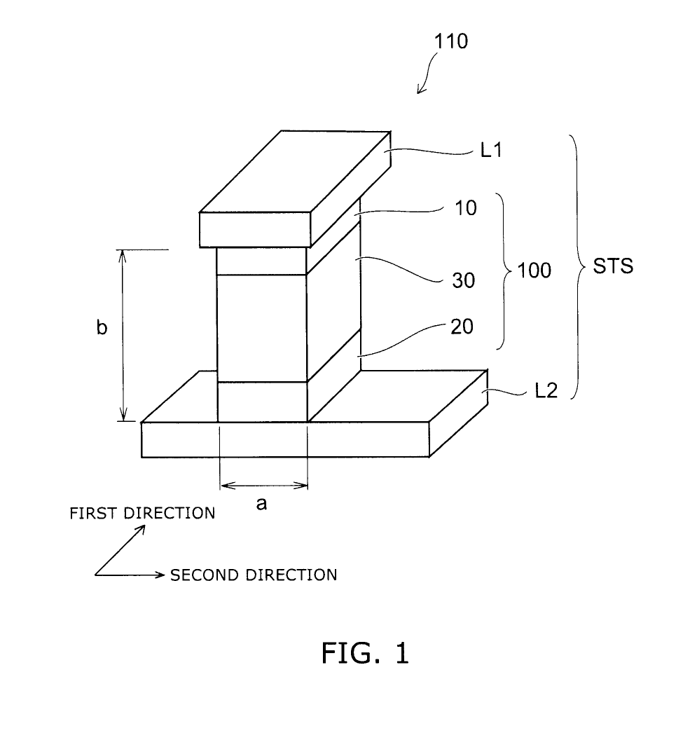

FIG. 1 is a schematic view illustrating the configuration of a nonvolatile memory device according to a first embodiment.

It is noted that FIG. 1 schematically shows the structure of one cross point in the three-dimensional cross-point structure described later.

As shown in FIG. 1, the nonvolatile memory device 110 according to the first embodiment includes an upper interconnect (first interconnect) L1 extending in a first direction, a lower interconnect (second interconnect) L2 spaced from the upper interconnect L1 and extending in a second direction crossing the first direction, and a functional layer (first functional layer) 100 provided at the crossing position between the upper interconnect L1 and the lower interconnect L2. The stacked structure (first stacked structure) STS includes the upper interconnect L1, the lower interconnect L2, and the functional layer 100.

The upper interconnect L1 is the bit line BL or the word line WL described later. On the other hand, the lower interconnect L2 is the word line WL or the bit line BL described later. FIG. 1 shows one upper interconnect L1 and one lower interconnect L2. In practice, a plurality of parallel upper interconnects L1 and a plurality of parallel lower interconnects L2 are provided so as to cross each other.

The functional layer 100 includes a metal layer 10, an opposed layer 20, and a semiconductor layer 30 provided therebetween. The semiconductor layer 30 is in contact with each of the metal layer 10 and the opposed layer 20. In the functional layer 100 illustrated in FIG. 1, the metal layer 10, the semiconductor layer 30, and the opposed layer 20 are provided in this order from the upper interconnect L1 toward the lower interconnect L2. However, these layers may be provided in the reverse order.

The functional layer 100 has the function of transitioning between different resistance states (hereinafter simply referred to as “transitioning function”), and the function of rectifying the current (hereinafter simply referred to as “rectifying function”). The portion achieving the transitioning function is a variable resistance element and the portion achieving the rectifying function is a rectifying element. The resistance states include a state of relatively high resistance (high resistance state) and a state of relatively low resistance (low resistance state). The functional layer 100 transitions between the high resistance state and the low resistance state by application of a prescribed voltage. The functional layer 100 has the rectifying function for determining the current characteristics depending on the direction. The rectifying function is realized by e.g. a PN diode.

In the nonvolatile memory device 110 according to the embodiment, the semiconductor layer 30 of the functional layer 100 combines part of the transitioning function and part of the rectifying function. Hence, as compared with the case of implementing these functions using separate layers, the layer thickness can be thinned, and the aspect ratio of the functional layer 100 can be reduced. The aspect ratio of the functional layer 100 is represented by b/a, where a is the length along the width direction of the interconnect layer (e.g., upper interconnect L1) in the functional layer 100, and b is the length along the direction perpendicular to the width direction. In the following description of the embodiment, it is assumed that the aspect ratio of the functional layer 100 is defined as “b/a”.

The cross-point structure of the nonvolatile memory device 110 is described.

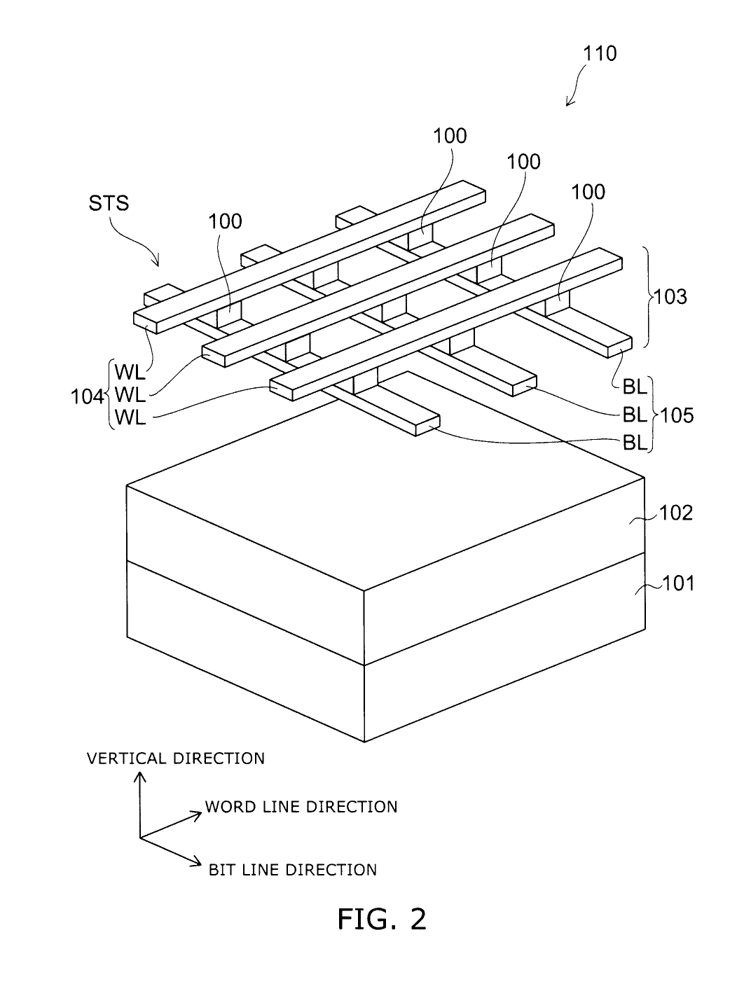

FIG. 2 is a schematic perspective view illustrating the cross-point structure of the nonvolatile memory device.

As shown in this figure, the nonvolatile memory device 110 according to the embodiment includes a silicon substrate 101. A driver circuit (not shown) for the nonvolatile memory device 110 is formed in an upper portion and on the upper surface of the silicon substrate 101. An interlayer insulating film 102 made of e.g. silicon oxide is provided on the silicon substrate 101 so as to cover the driver circuit. A memory cell unit 103 of the cross-point structure is provided on the interlayer insulating film 102. The stacked structure STS included in the memory cell unit 103 is configured to include a plurality of word lines WL constituting a common layer, a plurality of bit lines BL constituting a common layer, and a plurality of functional layers 100 provided at the cross points therebetween.

In the memory cell unit 103, a word line interconnect layer 104 and a bit line interconnect layer 105 are stacked via an insulating layer. The word line interconnect layer 104 is made of a plurality of word lines WL extending in one direction (hereinafter referred to as “word line direction”) parallel to the upper surface of the silicon substrate 101. The bit line interconnect layer 105 is made of a plurality of bit lines BL extending in a direction (hereinafter referred to as “bit line direction”) being parallel to the upper surface of the silicon substrate 101 and crossing, such as being orthogonal to, the word line direction.

One of the word line WL and the bit line BL is the upper interconnect L1, and the other is the lower interconnect L2. In the embodiment, by way of example, it is assumed that the word line WL is the upper interconnect L1, and the bit line BL is the lower interconnect L2.

The word line WL and the bit line BL are formed from e.g. tungsten (W). The adjacent word lines WL, the adjacent bit lines BL, and the word line WL and the bit line BL are not in contact with each other.

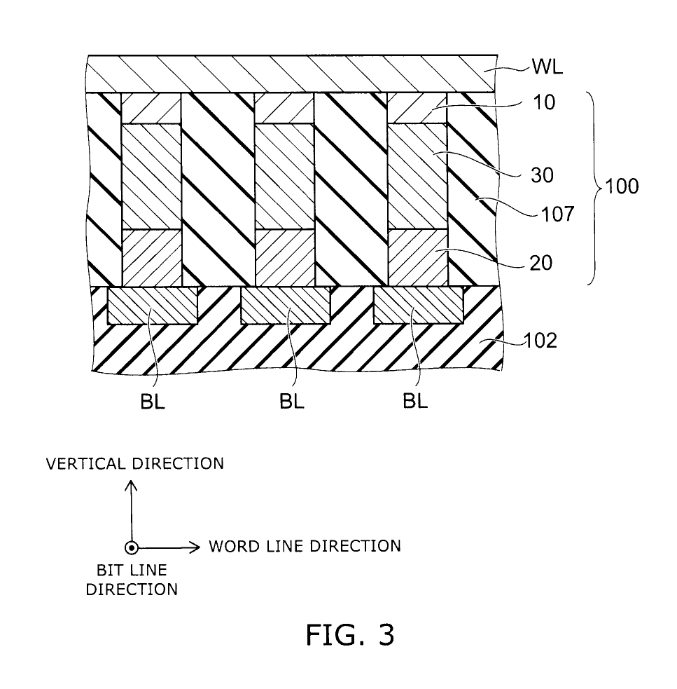

At the nearest point between each word line WL and each bit line BL, the functional layer 100 extending in the direction (hereinafter referred to as “vertical direction”) perpendicular to the upper surface of the silicon substrate 101 is provided. The functional layer 100 is formed like a pillar between the word line WL and the bit line BL. One functional layer 100 constitutes one memory cell. A memory cell is located at each nearest point of the word line WL and the bit line BL. Accordingly, the nonvolatile memory device 110 has a cross-point structure. An interlayer insulating film 107 (see FIG. 3) made of e.g. silicon oxide is buried among the word line WL, the bit line BL, and the pillar of the functional layer 100.

In the following, the configuration of the memory cell is described with reference to FIG. 3.

The configuration of the memory cell has two possibilities. In one case, the word line WL is located below the functional layer 100, and the bit line BL is located above the functional layer 100. In the other case, the bit line BL is located below the functional layer 100, and the word line WL is located above the functional layer 100. FIG. 3 shows pillars in which the bit line BL is located therebelow, and the word line WL is located thereabove.

In this memory cell, from bottom (bit line side) to top (word line side), the opposed layer 20, the semiconductor layer 30, and the metal layer 10 are stacked in this order. That is, the metal layer 10 is in contact with the semiconductor layer 30, and the semiconductor layer 30 is in contact with the opposed layer 20. The metal layer 10 is in contact with the word line WL, and the opposed layer 20 is in contact with the bit line BL. Connecting electrodes may be provided between the word line WL and the metal layer 10, and between the bit line BL and the opposed layer 20.

An interlayer insulating film 107 is buried between a plurality of functional layers 100 formed at the respective cross points in the same layer. This serves to insulate the functional layers 100 from each other and to support the pillar-shaped functional layers 100.

A method for manufacturing a nonvolatile memory device according to the embodiment is described.

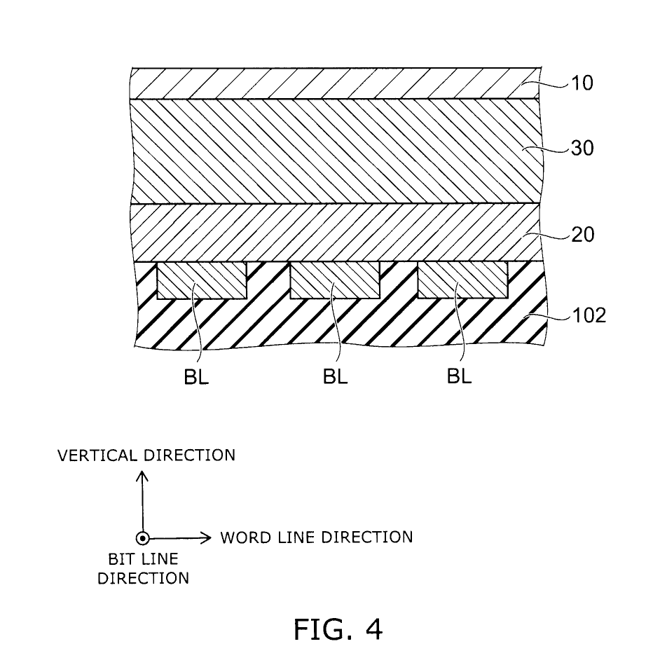

FIGS. 4 to 7 are process sectional views illustrating the method for manufacturing a nonvolatile memory device according to the embodiment.

First, a driver circuit for driving the memory cell unit 103 (see FIG. 2) is formed in the upper surface of a silicon substrate 101 (see FIG. 2). Next, an interlayer insulating film 102 is formed on the silicon substrate 101. Next, contacts (not shown) reaching the driver circuit are formed in the interlayer insulating film 102.

Next, as shown in FIG. 4, tungsten is buried in an upper portion of the interlayer insulating film 102 by e.g. a damascene process to form a plurality of bit lines BL parallel to each other so as to extend in the bit line direction. These bit lines BL form a bit line interconnect layer 105 (see FIG. 2).

Next, an opposed layer 20 is uniformly deposited on the bit line interconnect layer 105. A semiconductor layer 30 is uniformly deposited on the opposed layer 20. A metal layer 10 is uniformly deposited on the semiconductor layer 30.

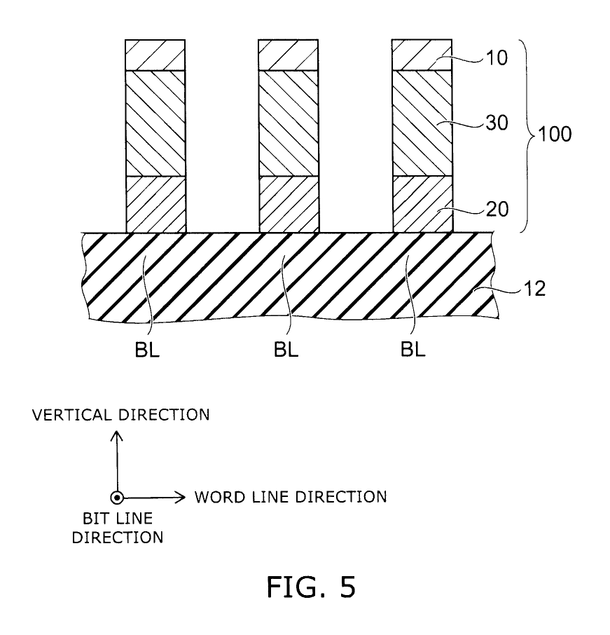

Next, a silicon oxide film using TEOS (tetraethyl orthosilicate) as a raw material, and a silicon nitride film are formed to form a mask material for patterning. This mask material is patterned by a lithography process to form a mask pattern (not shown). Next, this mask pattern is used as a mask to perform RIE (reactive ion etching) so that the metal layer 10, the semiconductor layer 30, and the opposed layer 20 are selectively removed and divided along both the word line direction and the bit line direction. Thus, a plurality of pillar-shaped functional layers 100 are formed on each bit line BL (see FIG. 5). The aspect ratio of the pillar of the functional layer 100 is e.g. 10 or less.

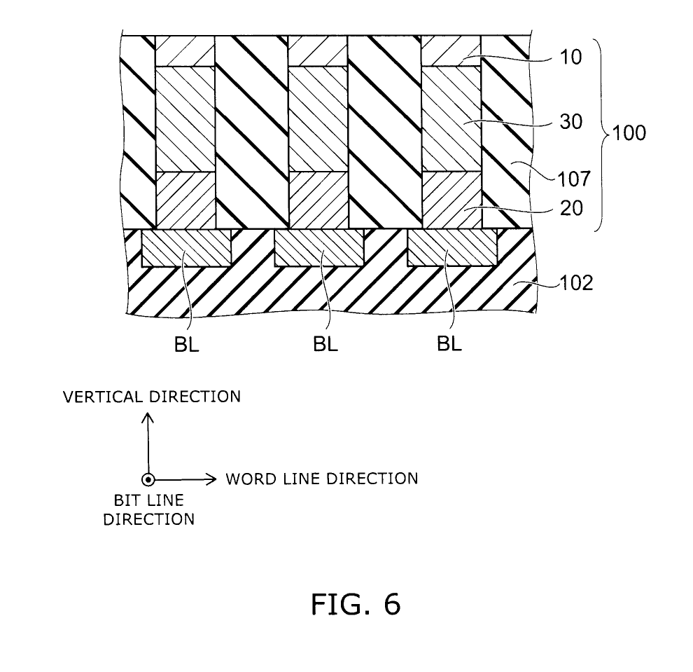

Next, as shown in FIG. 6, for instance, an insulating film such as a silicon oxide film is deposited by a CVD (chemical vapor deposition) process using TEOS as a raw material so as to bury the pillar-shaped functional layers 100. This insulating film constitutes an interlayer insulating film 107.

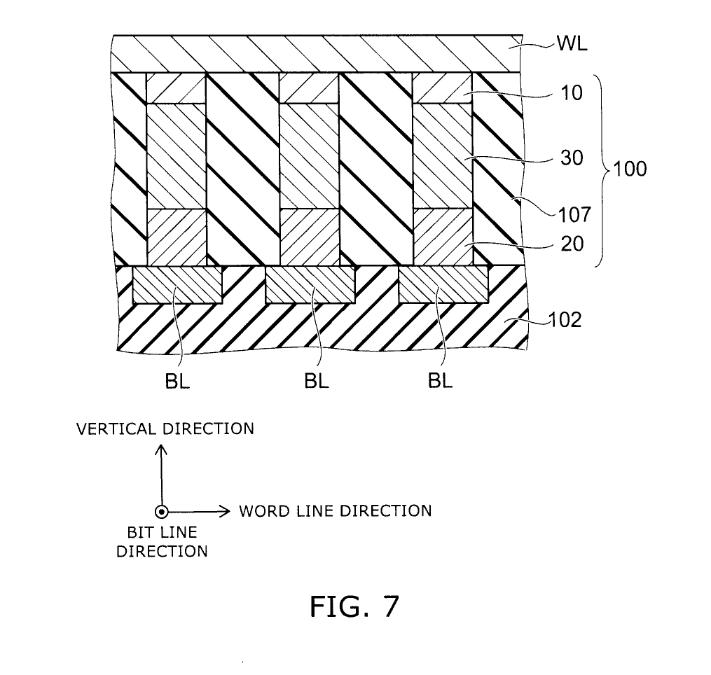

Next, as shown in FIG. 7, an interlayer insulating film (not shown) is further formed on the interlayer insulating film 107, and word lines WL are formed by a damascene process. More specifically, trenches are formed in a region of the interlayer insulating film where word lines WL are to be formed. An interconnect material such as tungsten is deposited to fill in the trench. Tungsten deposited outside the trench is removed by CMP. Thus, word lines WL made of tungsten are formed. These word lines WL form a word line interconnect layer 104 (see FIG. 2). Each word line WL is connected to the upper surface of a plurality of functional layers 100 arranged in the word line direction. Thus, each functional layer 100 is formed at a cross point between the word line WL and the bit line BL, and connected to the word line WL and the bit line BL.

Thus, the nonvolatile memory device 110 according to the embodiment is manufactured.

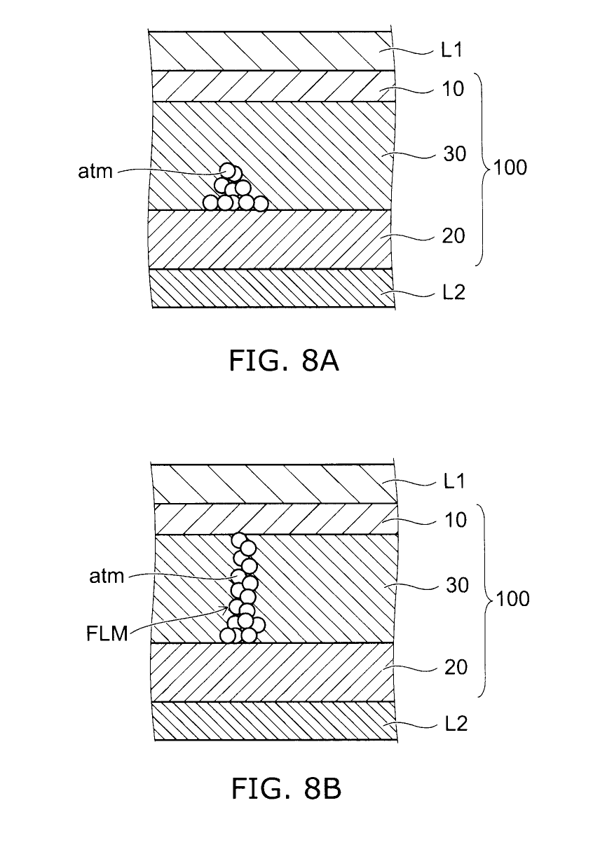

FIGS. 8A and 8B are schematic sectional views describing the state transition of the functional layer.

FIG. 8A illustrates the high resistance state, and FIG. 8B illustrates the low resistance state.

In the functional layer 100, atoms (metal atoms atm) of the metal (e.g., Ag) included in the metal layer 10 are diffused from the metal layer 10 into the semiconductor layer 30.

In the high resistance state shown in FIG. 8A, metal atoms atm in the semiconductor layer 30 are biased toward the opposed layer 20, for instance. That is, no filament FLM serving as a conduction path between the metal layer 10 and the opposed layer 20 is formed. Thus, the functional layer 100 is placed in the high resistance state (off state).

In the low resistance state shown in FIG. 8B, metal atoms atm in the semiconductor layer 30 are linked between the metal layer 10 and the opposed layer 20. That is, a filament FLM serving as a conduction path between the metal layer 10 and the opposed layer 20 is formed. Thus, the functional layer 100 is placed in the low resistance state (on state).

Here, the state transition is not limited to the presence and absence of the filament FLM formed from the metal atoms atm. For instance, depending on the composition of the semiconductor layer 30, a filament FLM may be formed by oxygen defects or ion conduction. The semiconductor layer 30 may be made of or include an insulator or a material close to insulator as long as such a filament FLM can be formed therein.

The metal layer 10 may be oxidized or nitridized as long as it enables the state transition operation by being stacked with the semiconductor layer 30.

The operation of the embodiment is described.

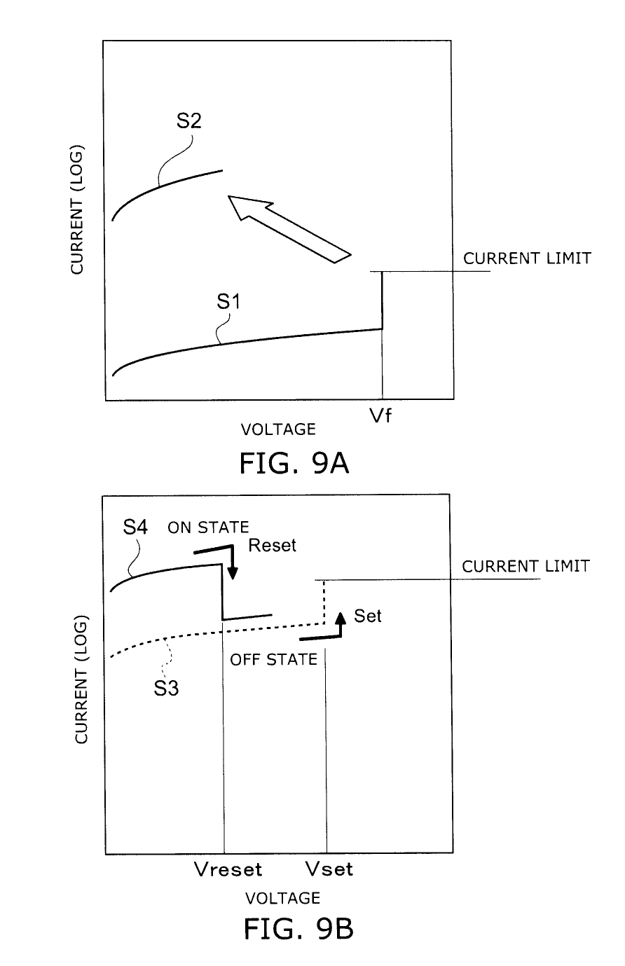

FIGS. 9A and 9B are graphs illustrating the operation of the nonvolatile memory device, where the horizontal axis represents voltage, and the vertical axis represents current.

FIG. 9A shows the forming operation, and FIG. 9B shows the set operation and the reset operation.

The solid line S1 shown in FIG. 9A represents the I-V characteristics of the functional layer in the initial state. As shown by the solid line S1, in the initial state, the functional layer 100 has a relatively high resistance. The voltage applied to this functional layer 100 in the initial state is gradually increased. Then, at a certain voltage (Vf), the functional layer 100 discontinuously transitions to the low resistance state represented by the solid line 52. This voltage Vf is called the forming voltage. The state represented by the solid line S2 is the aforementioned on state or off state, and has a lower resistance than the initial state represented by the solid line S1.

Here, as shown by the solid line S1, when the voltage applied to the functional layer reaches the forming voltage Vf, the resistance of the functional layer sharply decreases. If used as it is, a large current flows and causes damage to the functional layer. Thus, the driver circuit for supplying voltage is provided with a certain protection mechanism to block the current at the moment when the application voltage reaches the forming voltage Vf.

Furthermore, as shown by the dashed line S3 of FIG. 9B, if a set voltage Vset is applied to the functional layer in the high-resistance off state, the functional layer transitions to the low-resistance on state. This operation is called the “set operation”. Also in the set operation, the resistance of the functional layer sharply decreases. Thus, at the moment when the voltage reaches the set voltage Vset, the driver circuit blocks the current to prevent an excessive current from flowing in the resistance change film.

On the other hand, as shown by the solid line S4 of FIG. 9B, if a reset voltage Vreset is applied to the functional layer in the low-resistance on state, the functional layer transitions to the high-resistance off state. This operation is called the “reset operation”. In the reset operation, the resistance of the functional layer increases. No excessive current flows in the functional layer. By repeating the set operation and the reset operation, the functional layer can reversibly transition between the on state and the off state. Thus, the functional layer can be used as a memory element.

The operation of voltage application to the memory cell in performing the set operation and the reset operation is described.

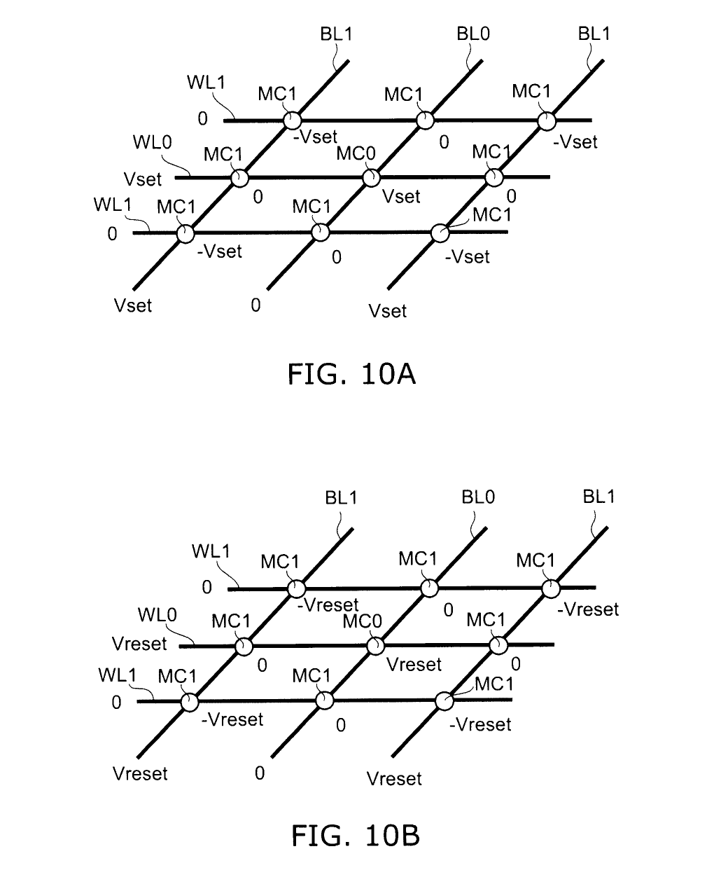

FIGS. 10A and 10B describe the unipolar operation.

More specifically, FIG. 10A describes the set operation, and FIG. 10B describes the reset operation.

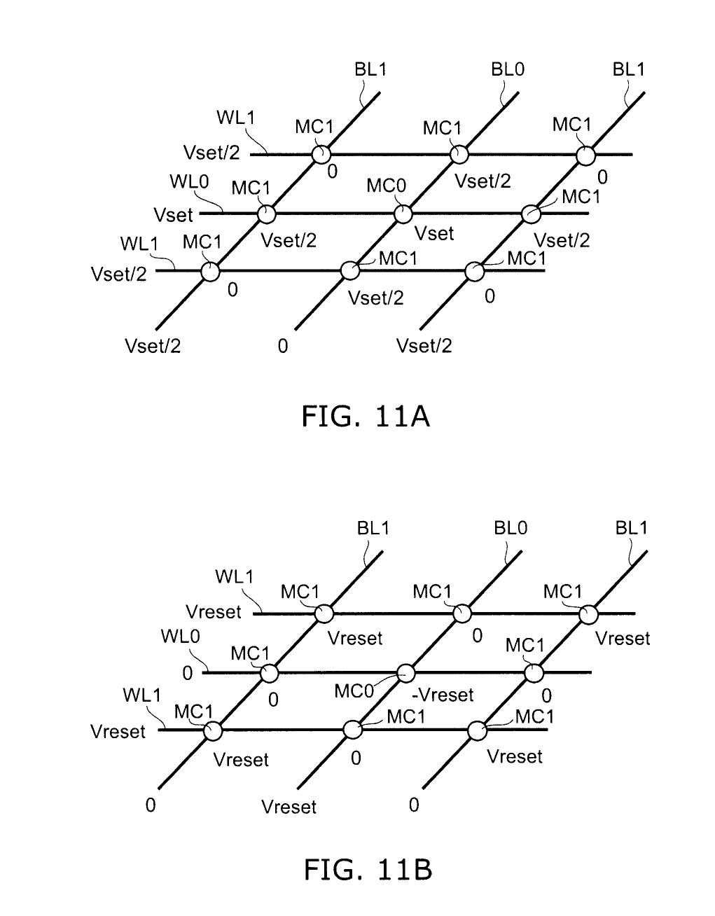

FIGS. 11A and 11B describe the bipolar operation.

More specifically, FIG. 11A describes the set operation, and FIG. 11B describes the reset operation.

Here, for clarity of description, at a total of nine cross points formed by three word lines WL and three bit lines BL, the state of the voltage applied to each memory cell is illustrated. In each figure, the memory cell is represented by a circle. Of the nine cross points, the selected cross point is the central memory cell MC0, and the non-selected cross points are the other memory cells MC1.

As shown in FIG. 10A, in the set operation in the unipolar operation, the word line WL0 connected to the selected memory cell MC0 is applied with the set voltage Vset, and the bit line BL0 is applied with a reference potential (e.g., 0 V). On the other hand, the word line WL1 connected to the non-selected memory cell MC1 is applied with the reference potential, and the bit line BL1 is applied with the set voltage Vset.

Thus, the selected memory cell MC0 is applied with the set voltage Vset. On the other hand, the non-selected memory cell MC1 is applied with the reference potential or −Vset.

The memory cells MC0 and MC1 are each provided with a select element. The set voltage Vset is applied only to the functional layer 100 of the memory cell MC0 applied with the set voltage Vset in one polarity. Thus, the set operation is performed in the functional layer 100 of the memory cell MC0. On the other hand, no voltage is applied to the functional layer 100 of the memory cell MC1 applied with −Vset or the reference potential in the other polarity. Thus, the set operation is not performed in the functional layer 100 of the memory cell MC1.

In the reset operation shown in FIG. 10B, the word line WL0 connected to the selected memory cell MC0 is applied with the reset voltage Vreset, and the bit line BL0 is applied with the reference potential (e.g., 0 V). On the other hand, the word line WL1 connected to the non-selected memory cell MC1 is applied with the reference potential, and the bit line BL1 is applied with the reset voltage Vreset.

The selected memory cell MC0 is applied with the reset voltage Vreset. On the other hand, the non-selected memory cell MC1 is applied with the reference potential or −Vreset.

Hence, the reset voltage Vreset is applied only to the functional layer 100 of the memory cell MC0 applied with the reset voltage Vreset in one polarity. Thus, the reset operation is performed in the functional layer 100 of the memory cell MC0. On the other hand, no voltage is applied to the functional layer 100 of the memory cell MC1 applied with −Vreset or the reference potential in the other polarity. Thus, the reset operation is not performed in the functional layer 100 of the memory cell MC1.

Here, the operation scheme of the set operation and the reset operation shown in FIGS. 10A and 10B may be reversed.

As shown in FIG. 11A, in the set operation in the bipolar operation, the word line WL0 connected to the selected memory cell MC0 is applied with the set voltage Vset, and the bit line BL0 is applied with the reference potential (e.g., 0 V). On the other hand, the word line WL1 connected to the non-selected memory cell MC1 is applied with Vset/2, and the bit line BL1 is applied with Vset/2.

The selected memory cell MC0 is applied with the set voltage Vset exceeding the breakdown voltage of the select element. On the other hand, the non-selected memory cell MC1 is applied with the reference potential or Vset/2 not exceeding the breakdown voltage of the select element.

Hence, the set voltage Vset is applied only to the functional layer 100 of the memory cell MC0 applied with the set voltage Vset. Thus, the set operation is performed in the functional layer 100 of the memory cell MC0. On the other hand, the set voltage Vset is not applied to the memory cell MC1. Thus, the set operation is not performed in the memory cell MC1.

In the reset operation shown in FIG. 11B, the word line WL0 connected to the selected memory cell MC0 is applied with the reference potential, and the bit line BL0 is applied with the reset voltage Vreset. On the other hand, the word line WL1 connected to the non-selected memory cell MC1 is applied with the reset voltage Vreset, and the bit line BL1 is applied with the reference potential.

Hence, −Vreset is applied only to the functional layer 100 of the memory cell MC0 applied with −Vreset in the opposite polarity of the reset voltage Vreset. Thus, the reset operation is performed in the functional layer 100 of the memory cell MC0. On the other hand, no voltage is applied to the functional layer 100 of the memory cell MC1 applied with the reset voltage Vreset or the reference potential. Thus, the reset operation is not performed in the functional layer 100 of the memory cell MC1.

Here, the operation scheme of the set operation and the reset operation shown in FIGS. 11A and 11B may be reversed.

The foregoing operations are illustrative only. The voltage application direction of the reset operation and the set operation may be reversed in polarity. For instance, in the bipolar operation, the set voltage may be +Vset and the reset voltage may be −Vreset. Conversely, the set voltage may be −Vset and the reset voltage may be +Vreset. As an alternative scheme, both the set operation and the reset operation may use ±Vset/2 and ±Vreset/2.

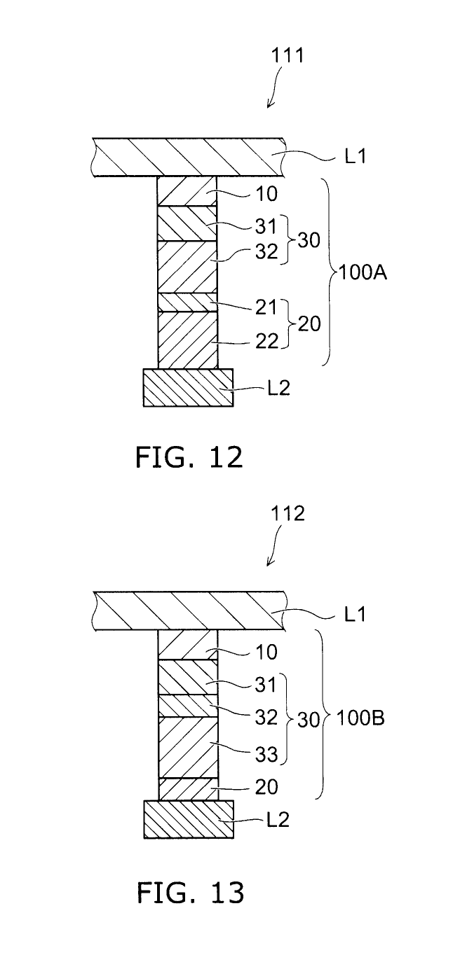

FIGS. 12 to 19 are schematic sectional views describing examples of the functional layer.

For convenience of description, each figure illustrates a schematic cross section of one functional layer provided at one cross point.

The functional layer 100A of a nonvolatile memory device 111 shown in FIG. 12 includes a metal layer 10, an opposed layer 20, and a semiconductor layer 30. The opposed layer 20 includes a first layer 21 and a second layer 22. The semiconductor layer 30 includes a first layer 31 and a second layer 32.

The metal layer 10 includes e.g. silver (Ag), hafnium (Hf), or nickel (Ni). The first layer 21 of the opposed layer 20 includes an intrinsic semiconductor (e.g., silicon (Si)). The second layer 22 of the opposed layer 20 includes a second conductivity type semiconductor (e.g., n⁺-type Si). The first layer 31 of the semiconductor layer 30 includes an intrinsic semiconductor (e.g., Si). The second layer 32 of the semiconductor layer 30 includes a first conductivity type semiconductor (e.g., p⁺-type Si). The symbol “+” attached to the conductivity type indicates higher impurity concentration relative to “−”.

In this functional layer 100A, Si of e.g. p⁺-type (first semiconductor region) included in the second layer 32 of the semiconductor layer 30, intrinsic Si (first intrinsic semiconductor region) included in the first layer 21 of the opposed layer 20, and Si of e.g. n⁺-type (second semiconductor region) included in the second layer 22 of the opposed layer 20 constitute a PIN (p-type semiconductor—intrinsic semiconductor—N-type semiconductor) diode.

In this PIN diode, Si of e.g. p⁺-type included in the second layer 32 of the semiconductor layer 30 has a transitioning function (memory function) in conjunction with intrinsic Si included in the first layer 31. That is, the second layer 32 of the semiconductor layer 30 combines part of the transitioning function and part of the rectifying function of the PIN diode. Thus, the second layer 32 included in the functional layer 100A combines part of the transitioning function and part of the rectifying function. The aspect ratio of the functional layer 100A can be made smaller than in the case of no combining.

Here, in the structure of the PIN diode, the aforementioned p-type and n-type may be vertically reversed.

Furthermore, the first layer 21 of the opposed layer 20 may be made of n⁺-type Si like the second layer 22 so that the second layer 32 and the opposed layer 20 constitute a PN diode.

The functional layer 100B of a nonvolatile memory device 112 shown in FIG. 13 includes a metal layer 10, an opposed layer 20, and a semiconductor layer 30. The semiconductor layer 30 includes a first layer 31, a second layer 32, and a third layer 33.

The metal layer 10 includes e.g. Ag, Hf, or Ni. The opposed layer 20 includes a second conductivity type semiconductor (e.g., n⁻-type Si). The first layer 31 of the semiconductor layer 30 includes an intrinsic semiconductor (e.g., Si). The second layer 32 of the semiconductor layer 30 includes a second conductivity type semiconductor (e.g., n⁻-type Si). The third layer 33 of the semiconductor layer 30 includes a first conductivity type semiconductor (e.g., p⁺-type Si).

In this functional layer 1008, Si of e.g. n⁻-type (third semiconductor region) included in the second layer 32 of the semiconductor layer 30, Si of e.g. p⁺-type (first semiconductor region) included in the third layer 33, and Si of e.g. n⁻-type (second semiconductor region) included in the opposed layer 20 constitute an NPN (n-type semiconductor—p-type semiconductor—n-type semiconductor) element.

In this NPN element, Si of e.g. n⁻-type included in the second layer 32 of the semiconductor layer 30 and Si of e.g. p⁺-type included in the third layer 33 have a transitioning function in conjunction with intrinsic Si included in the first layer 31. That is, the second layer 32 and the third layer 33 of the semiconductor layer 30 combine part of the transitioning function and part of the rectifying function of the NPN element. Thus, the second layer 32 and the third layer 33 included in the functional layer 100B combine part of the transitioning function and part of the rectifying function. The aspect ratio of the functional layer 100B can be made smaller than in the case of no combining.

The functional layer 100C of a nonvolatile memory device 113 shown in FIG. 14 includes a metal layer 10, an opposed layer 20, and a semiconductor layer 30. The opposed layer 20 includes a first layer 21 and a second layer 22. The semiconductor layer 30 includes a first layer 31 and a second layer 32.

The metal layer 10 includes e.g. Ag, Hf, or Ni. The first layer 21 of the opposed layer 20 includes a second conductivity type semiconductor (e.g., n⁻-type Si). The second layer 22 of the opposed layer 20 includes a first conductivity type semiconductor (e.g., p⁺-type Si). The first layer 31 of the semiconductor layer 30 includes an intrinsic semiconductor (e.g., Si). The second layer 32 of the semiconductor layer 30 includes a first conductivity type semiconductor (e.g., p⁺-type Si).

In this functional layer 100C, Si of e.g. p⁺-type (first semiconductor region) included in the second layer 32 of the semiconductor layer 30, Si of e.g. n⁻-type (second semiconductor region) included in the first layer 21 of the opposed layer 20, and Si of e.g. p⁺-type (fourth semiconductor region) included in the second layer 22 of the opposed layer 20 constitute a PNP (p-type semiconductor—n-type semiconductor—p-type semiconductor) element.

In this PNP element, Si of e.g. p⁺-type included in the second layer 32 of the semiconductor layer 30 and Si of e.g. n⁻-type included in the first layer 21 of the opposed layer 20 have a transitioning function in conjunction with intrinsic Si included in the first layer 31. That is, the second layer 32 of the semiconductor layer 30 and the first layer 21 of the opposed layer 20 combine part of the transitioning function and part of the rectifying function of the PNP element. Thus, the second layer 32 and the first layer 21 of the opposed layer 20 included in the functional layer 100C combine part of the transitioning function and part of the rectifying function. The aspect ratio of the functional layer 100C can be made smaller than in the case of no combining.

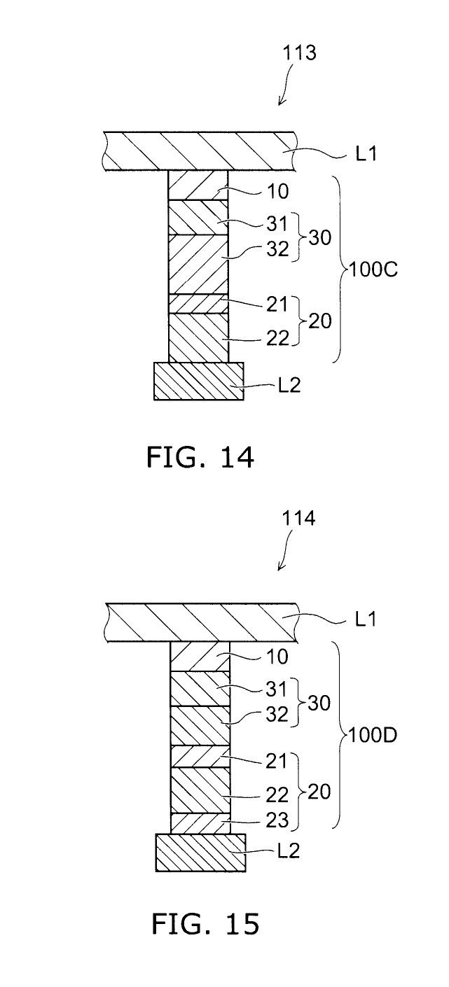

The functional layer 100D of a nonvolatile memory device 114 shown in FIG. 15 includes a metal layer 10, an opposed layer 20, and a semiconductor layer 30. The opposed layer 20 includes a first layer 21, a second layer 22, and a third layer 23. The semiconductor layer 30 includes a first layer 31 and a second layer 32.

The metal layer 10 includes e.g. Ag, Hf, or Ni. The first layer 21 of the opposed layer 20 includes a second conductivity type semiconductor (e.g., n⁻-type Si). The second layer 22 of the opposed layer 20 includes a first conductivity type semiconductor (e.g., p⁺-type Si). The third layer 23 of the opposed layer 20 includes a second conductivity type semiconductor (e.g., n⁻-type Si). The first layer 31 of the semiconductor layer 30 includes an intrinsic semiconductor (e.g., Si). The second layer 32 of the semiconductor layer 30 includes a first conductivity type semiconductor (e.g., p⁺-type Si).

In this functional layer 100D, Si of e.g. p⁺-type (first semiconductor region) included in the second layer 32 of the semiconductor layer 30, Si of e.g. n⁻-type (second semiconductor region) included in the first layer 21 of the opposed layer 20, Si of e.g. p⁺-type (fourth semiconductor region) included in the second layer 22, and an n⁻-type semiconductor (e.g., n⁻-type Si) (fifth semiconductor region) included in the third layer 23 constitute a PNPN (p-type semiconductor—n-type semiconductor—p-type semiconductor—n-type semiconductor) element.

In this PNPN element, Si of e.g. p⁺-type included in the second layer 32 of the semiconductor layer 30 has a transitioning function in conjunction with intrinsic Si included in the first layer 31. That is, the second layer 32 of the semiconductor layer 30 combines part of the transitioning function and part of the rectifying function of the PNPN element. Thus, the second layer 32 included in the functional layer 100D combines part of the transitioning function and part of the rectifying function. The aspect ratio of the functional layer 100D can be made smaller than in the case of no combining.

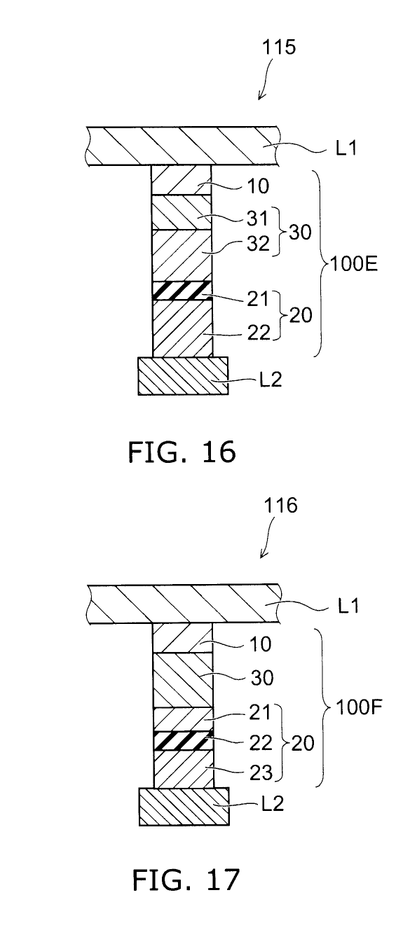

The functional layer 100E of a nonvolatile memory device 115 shown in FIG. 16 includes a metal layer 10, an opposed layer 20, and a semiconductor layer 30. The opposed layer 20 includes a first layer 21 and a second layer 22. The semiconductor layer 30 includes a first layer 31 and a second layer 32.

The metal layer 10 includes e.g. Ag, Hf, or Ni. The first layer 21 of the opposed layer 20 includes an insulator. The second layer 22 of the opposed layer 20 includes a first conductivity type semiconductor (e.g., p⁺-type Si). The first layer 31 of the semiconductor layer 30 includes an intrinsic semiconductor (e.g., Si). The second layer 32 of the semiconductor layer 30 includes a first conductivity type semiconductor (e.g., p⁺-type Si).

In this functional layer 100E, Si of e.g. p⁺-type (first semiconductor region) included in the second layer 32 of the semiconductor layer 30, the insulator (first insulator region) included in the first layer 21 of the opposed layer 20, and Si of e.g. p⁺-type (sixth semiconductor region) included in the second layer 22 of the opposed layer 20 constitute a SIS (semiconductor—insulator—semiconductor) element.

In this SIS element, Si of e.g. p⁺-type included in the second layer 32 of the semiconductor layer 30 has a transitioning function in conjunction with intrinsic Si included in the first layer 31. That is, the second layer 32 of the semiconductor layer 30 combines part of the transitioning function and part of the rectifying function of the SIS element. Thus, the second layer 32 included in the functional layer 100E combines part of the transitioning function and part of the rectifying function. The aspect ratio of the functional layer 100E can be made smaller than in the case of no combining.

In the functional layer 100E illustrated in FIG. 16, by way of example, the second layer 32 of the semiconductor layer 30 and the second layer 22 of the opposed layer 20 both have p⁺-type conductivity. However, they may be of n⁺-type. Alternatively, one of the second layers 22 and 32 may be of n⁺-type, and the other may be of p⁺-type. An intrinsic, p⁻-type, or n⁻-type semiconductor layer may be interposed between the aforementioned p⁺-type or n⁺-type second layer 22 and the first layer 21 of insulator to relax the electric field. Thus, by adjusting carrier excitation, the operating point of Vset and Vreset can be changed.

The functional layer 100F of a nonvolatile memory device 116 shown in FIG. 17 includes a metal layer 10, an opposed layer 20, and a semiconductor layer 30. The opposed layer 20 includes a first layer 21, a second layer 22, and a third layer 23.

The metal layer 10 includes e.g. Ag, Hf, or Ni. The first layer 21 of the opposed layer 20 includes a metal. The second layer 22 of the opposed layer 20 includes an insulator. The third layer 23 of the opposed layer 20 includes a first conductivity type semiconductor (e.g., p⁺-type Si). The semiconductor layer 30 includes an intrinsic semiconductor (e.g., Si).

In this functional layer 100F, the metal (first metal region) included in the first layer 21 of the opposed layer 20, the insulator (second insulator region) included in the second layer 22, and Si of e.g. p⁺-type (seventh semiconductor region) included in the third layer 23 constitute a MIS (metal—insulator—semiconductor) element. The configuration of this MIS element may include e.g. intrinsic Si (third intrinsic semiconductor region) included in the semiconductor layer 30 to constitute an SMIS (semiconductor—metal—insulator—semiconductor) element.

In this MIS element, the metal included in the first layer 21 of the opposed layer 20 has a transitioning function in conjunction with intrinsic Si included in the semiconductor layer 30. That is, the first layer 21 of the opposed layer 20 combines part of the transitioning function and part of the rectifying function of the MIS element. Thus, the first layer 21 included in the functional layer 100F combines part of the transitioning function and part of the rectifying function. The aspect ratio of the functional layer 100F can be made smaller than in the case of no combining.

Furthermore, the work function of the metal in the MIS element portion can be adjusted by selecting its material to change the electrical characteristics. For instance, the current can be taken at low voltage by using a metal having high Fermi level. The on/off ratio can be changed also by using a multilayer structure in the insulator of the second layer 22. For instance, a thin insulating film having a high barrier on the electron injection side can be provided. Then, electrons flow easily from the high barrier side, and difficultly from the opposite side (low barrier side). By such adjustment, the electrical characteristics can be adjusted.

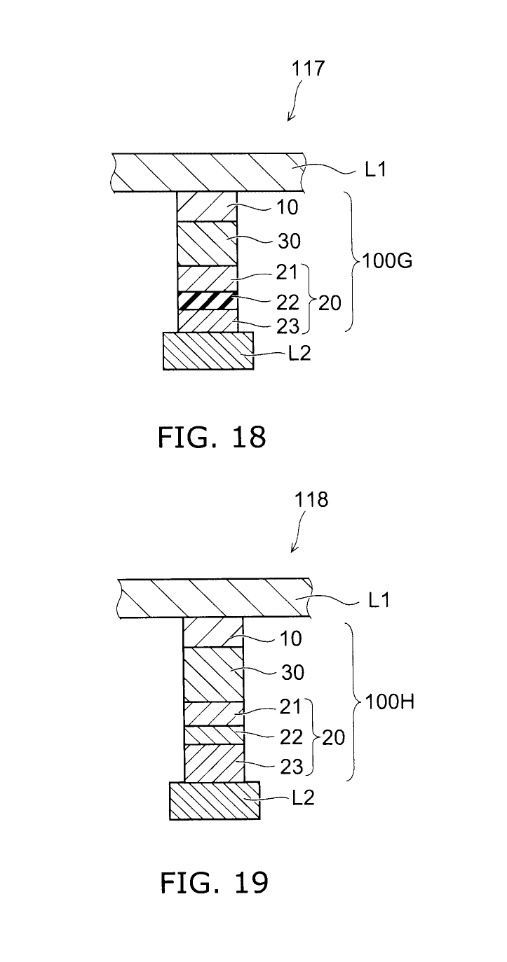

The functional layer 100G of a nonvolatile memory device 117 shown in FIG. 18 includes a metal layer 10, an opposed layer 20, and a semiconductor layer 30. The opposed layer 20 includes a first layer 21, a second layer 22, and a third layer 23.

The metal layer 10 includes e.g. Ag, Hf, or Ni. The first layer 21 of the opposed layer 20 includes a metal. The second layer 22 of the opposed layer 20 includes an insulator. The third layer 23 of the opposed layer 20 includes a metal. The semiconductor layer 30 includes an intrinsic semiconductor (e.g., Si).

In this functional layer 100G, the metal (second metal region) included in the first layer 21 of the opposed layer 20, the insulator (second insulator region) included in the second layer 22, and the metal (third metal region) included in the third layer 23 constitute a MIM (metal—insulator—metal) element.

In this MIM element, the metal included in the first layer 21 of the opposed layer 20 has a transitioning function in conjunction with intrinsic Si included in the semiconductor layer 30. That is, the first layer 21 of the opposed layer 20 combines part of the transitioning function and part of the rectifying function of the MIM element. Thus, the first layer 21 included in the functional layer 100G combines part of the transitioning function and part of the rectifying function. The aspect ratio of the functional layer 100G can be made smaller than in the case of no combining.

Furthermore, the work function of the metal in the MIM element portion can be adjusted by selecting its material to change the electrical characteristics. For instance, the current can be taken at low voltage by using a metal having high Fermi level. The on/off ratio can be changed also by using a multilayer structure in the insulator of the second layer 22. For instance, a thin insulating film having a high barrier on the electron injection side can be provided. Then, electrons flow easily from the high barrier side, and difficultly from the opposite side (low barrier side). By such adjustment, the electrical characteristics can be adjusted.

The functional layer 100H of a nonvolatile memory device 118 shown in FIG. 19 includes a metal layer 10, an opposed layer 20, and a semiconductor layer 30. The opposed layer 20 includes a first layer 21, a second layer 22, and a third layer 23.

The metal layer 10 includes e.g. Ag, Hf, or Ni. The first layer 21 of the opposed layer 20 includes e.g. a p⁺-type semiconductor. The second layer 22 of the opposed layer 20 includes an intrinsic semiconductor. The third layer 23 of the opposed layer 20 includes a metal. The semiconductor layer 30 includes an intrinsic semiconductor (e.g., Si).

In this functional layer 100H, the p⁺-type semiconductor (eighth semiconductor region) included in the first layer 21 of the opposed layer 20, the intrinsic semiconductor (second intrinsic semiconductor region) included in the second layer 22, and the metal (fourth metal region) included in the third layer constitute a PIM (p-type semiconductor—intrinsic semiconductor—metal) element.

In this PIM element, the semiconductor included in the first layer 21 of the opposed layer 20 has a transitioning function in conjunction with intrinsic Si included in the semiconductor layer 30. That is, the first layer 21 of the opposed layer 20 combines part of the transitioning function and part of the rectifying function of the PIM element. Thus, the first layer 21 included in the functional layer 100H combines part of the transitioning function and part of the rectifying function. The aspect ratio of the functional layer 100H can be made smaller than in the case of no combining. For convenience of description, the variable resistance element constituting the transitioning function may include the semiconductor layer 30 and the rectifying element constituting the rectifying function may be in contact with the semiconductor layer 30.

Furthermore, the work function of the metal in the PIM element portion can be adjusted by selecting its material to change the electrical characteristics. For instance, the current can be taken at low voltage by using a metal having high Fermi level. The semiconductor included in the first layer 21 may be of n-type instead of p-type. The structure of the PIM element may be vertically reversed. Moreover, segregated n-type impurity may be inserted at the interface of the metal and the intrinsic semiconductor of the PIM element (in the case of an NIM element, p-type impurity is segregated). By ultrathin segregation, the PIM element is not turned to PIN, but the characteristics can still be adjusted as PIM.

In the above functional layers 100A-100H, a connecting electrode may be provided between the metal layer 10 and the upper interconnect L1. In the functional layers 100A-100H, a connecting electrode may be provided between the opposed layer 20 and the lower interconnect L2.

### Second Embodiment

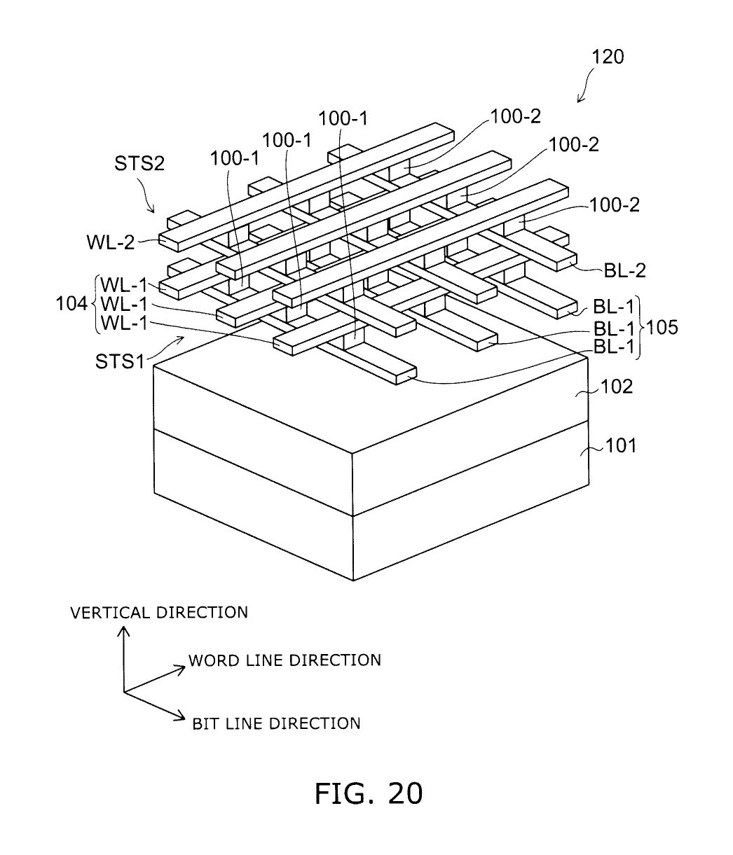

FIG. 20 is a schematic perspective view illustrating the structure of a nonvolatile memory device according to a second embodiment.

As shown in FIG. 20, in the nonvolatile memory device 120 according to the embodiment, a stacked structure (first stacked structure) STS1 and a stacked structure (second stacked structure) STS2 are vertically stacked.

The stacked structure STS1 includes word lines WL-1 as first upper interconnects L1, bit lines BL-1 as first lower interconnects L2, and first functional layers 100-1 provided at cross points of the word lines WL-1 and the bit lines BL-1.

The stacked structure STS2 includes word lines WL-2 as second upper interconnects L1, bit lines BL-2 as second lower interconnects L2, and second functional layers 100-2 provided at cross points of the word lines WL-2 and the bit lines BL-2.

For the functional layer 100-1 of the stacked structure STS1, one of the aforementioned functional layers 100A-100H is used. For the functional layer 100-2 of the stacked structure STS2, one of the aforementioned functional layers 100A-100H is used.

The structures of the functional layer 100-1 and the functional layer 100-2 may be identical or different.

Even if the same structure is used for the functional layer 100-1 and the functional layer 100-2, the metal layer 10, the opposed layer 20, and the semiconductor layer 30 may each be different in material and composition.

By using any of the functional layers 100A-100H for the functional layers 100-1 and 100-2, the aspect ratio can be reduced. Thus, in the nonvolatile memory device 120 with the stacked structures STS1 and STS2 stacked therein, the effect of suppressing the aspect ratio of the functional layer 100 is exhibited more significantly.

In the nonvolatile memory device 120 illustrated in FIG. 20, the stacked structures STS are vertically stacked in two stages. However, the stacked structures STS may be stacked in three or more stages. With the increase of the number of stacked stages, the effect of suppressing the aspect ratio of the functional layer 100 is made significant.

### Third Embodiment

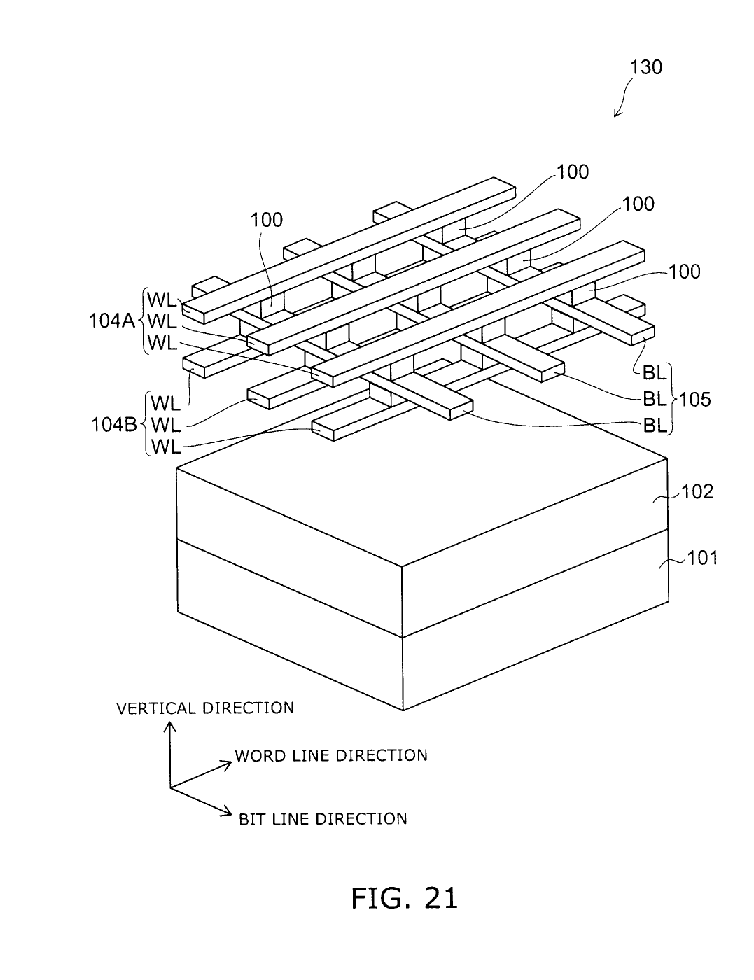

FIG. 21 is a schematic perspective view illustrating the structure of a nonvolatile memory device according to a third embodiment.

The nonvolatile memory device 130 includes a first word line interconnect layer 104A including a plurality of word lines (first interconnects) WL extending in the word line direction, a bit line interconnect layer 105 spaced from the first word line interconnect layer 104A and including a plurality of bit lines (second interconnects) BL extending in the bit line direction, a second word line interconnect layer 104B spaced from the first word line interconnect layer 104A and the bit line interconnect layer 105 and including a plurality of word lines (third interconnects) WL extending in the word line direction, and functional layers 100 provided at crossing positions of the interconnects. The functional layer 100 includes a metal layer 10, an opposed layer 20, and a semiconductor layer 30 provided therebetween.

In this nonvolatile memory device 130, the bit line BL provided between the two vertically stacked functional layers 100 is shared by the two functional layers 100. The functional layer 100 can be one of the aforementioned functional layers 100A-100H. The functional layer 100 has a transitioning function and a rectifying function.

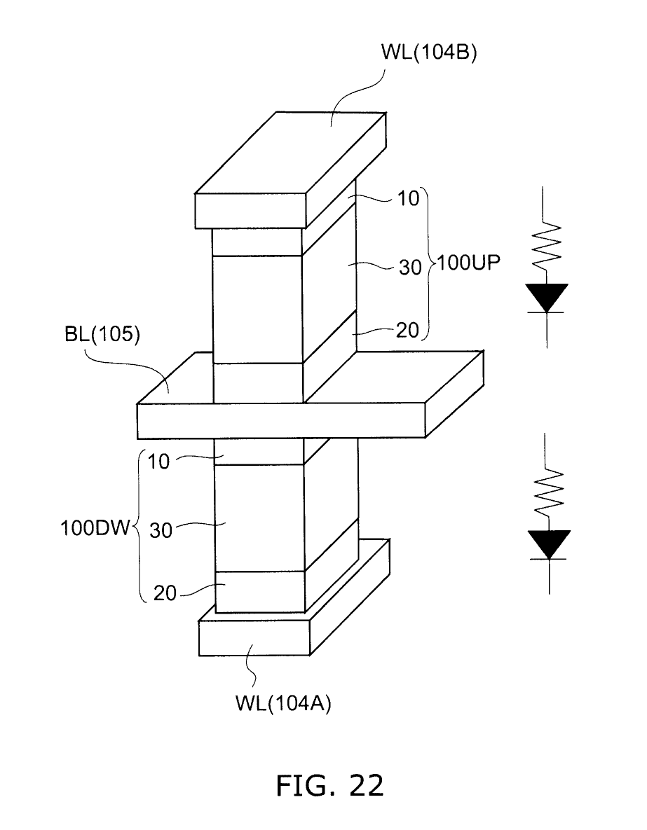

FIG. 22 is a schematic perspective view illustrating the configuration of the upper and lower functional layer at the cross point.

The cross point lies at the crossing position of a word line WL and a bit line BL. At the cross point, a functional layer 100 (100UP and 100DW) including a metal layer 10, an opposed layer 20, and a semiconductor layer 30 is provided. The functional layer 100 includes the metal layer 10, the semiconductor layer 30, and the opposed layer 20 in this order or the reverse order from the word line WL toward the bit line BL.

For instance, the upper functional layer 100UP illustrated in FIG. 22 includes the metal layer 10, the semiconductor layer 30, and the opposed layer 20 in this order from the word line WL of the second word line interconnect layer 104B toward the bit line BL of the bit line interconnect layer 105. The lower functional layer 100DW includes the opposed layer 20, the semiconductor layer 30, and the metal layer 10 in this order from the word line WL of the first word line interconnect layer 104A toward the bit line BL of the bit line interconnect layer 105.

The functional layers 100UP and 100DW depend on the order of forming the metal layer 10, the semiconductor layer 30, and the opposed layer 20, and the selection of the semiconductor conductivity type. Accordingly, the functional layers 100UP and 100DW are changed in the arrangement order of the portion achieving the transitioning function and the portion achieving the rectifying function, and in the rectifying direction of the rectifying function.

For instance, in the functional layer 100UP, the portion achieving the transitioning function and the portion achieving the rectifying function are provided in this order from the word line WL of the second word line interconnect layer 104B toward the bit line BL. The functional layer 100UP has a rectifying function in which the forward direction is directed from the word line WL of the second word line interconnect layer 104B toward the bit line BL. On the other hand, in the functional layer 100DW, the portion achieving the transitioning function and the portion achieving the rectifying function are provided in this order from the bit line BL toward the word line WL of the first word line interconnect layer 104A. The functional layer 100DW has a rectifying function in which the forward direction is directed from the bit line BL toward the word line WL of the first word line interconnect layer 104A.

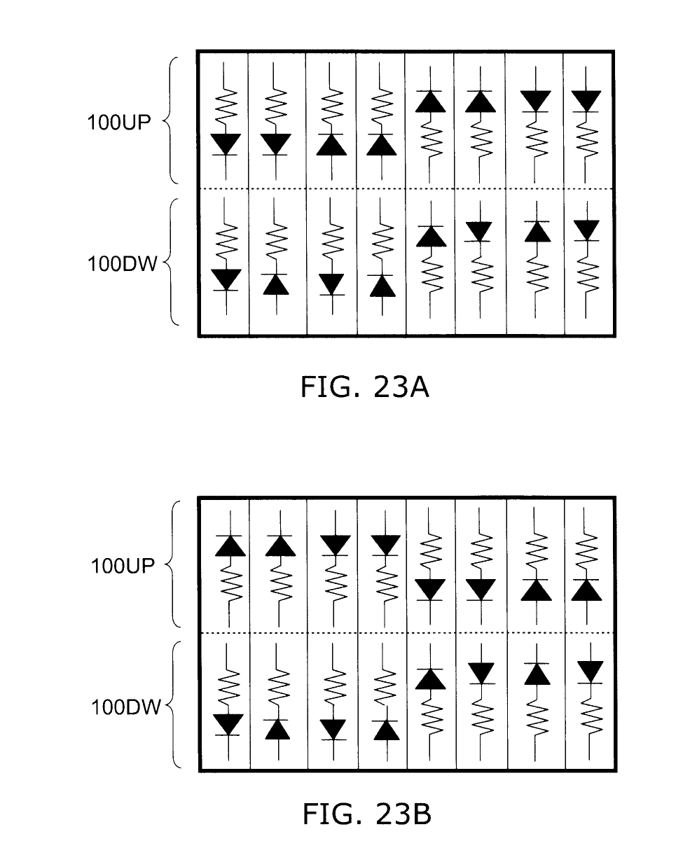

FIGS. 23A and 23B show example combinations of the arrangement of the functional portions and the rectifying direction of the functional layers.

In these figures, the transitioning function is represented by the resistor symbol, and the rectifying function is represented by the diode symbol.

In each of FIGS. 23A and 23B, the upper row corresponds to the functional layers 100UP, and the lower row corresponds to the functional layers 100DW.

There are 16 possibilities in selecting the combination of the arrangement order of the portion achieving the transitioning function and the portion achieving the rectifying function, and the rectifying direction of the rectifying function. By selection of these combinations, various memory operations can be realized.

Specific examples of the material of each layer used in the stacked structure STS are described.

### <Semiconductors>

Semiconductors used in the semiconductor layer 30 and the opposed layer 20 include e.g. substances having a band gap of 0.1 eV or more and 10 eV or less. The semiconductors include single crystals and polycrystals.

The semiconductors include e.g. Si, SiGe, SiC, Ge, C, GaAs, oxide semiconductors, nitride semiconductors, carbide semiconductors, and sulfide semiconductors.

P-type semiconductors include e.g. p⁺-type Si, TiO₂, ZrO₂, InZnOₓ, ITO, SnO₂:Sb, ZnO:Al, AgSbO₃, InGaZnO₄, and ZnO.SnO₂.

N-type semiconductors include e.g. n⁺-type Si, NIOₓ, ZnO.Rh₂O₃, ZnO:N, and La₂CuO_{4+d}.

### <Insulators>

The insulator of the SIS element of the functional layer 100E, the MIS (SMIS) element of the functional layer 100F, and the MIM element of the functional layer 100G is selected from e.g. the following materials.
(1) Oxides

(1-1) One of, or a combination of a plurality of, e.g. SiO₂, Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, and AlSiO.

(1-2) AB₂O₄

where A and B are identical or different elements, and one of, or a combination of a plurality of, Al, Sc, Ti, V, Cr, Mn, Fe, Co, Ni, Cu, Zn, Ga, and Ge.

For instance, Fe₃O₄, FeAl₂O₄, Mn₁₊ₓAl₂₋ₓO_{4+y}, Co₁₊ₓAl₂₋ₓO_{4+y}, and MnOₓ.

(1-3) ABO₃

where A and B are identical or different elements, and constituted by one of, or a combination of a plurality of, Al, La, Hf, Ta, W, Re, Os, Ir, Pt, Au, Hg, Tl, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn.

For instance, LaAlO₃, SrHfO₃, SrZrO₃, and SrTiO₃.
(2) Oxynitrides

(2-1) One of, or a combination of a plurality of, e.g. SiON, AlON, YON, LaON, GdON, CeON, TaON, HfON, ZrON, TiON, LaAlON, SrHfON, SrZrON, SrTiON, HfSiON, HfAlON, ZrSiON, ZrAlON, and AlSiON.

(2-2) Materials in which the oxygen element of the aforementioned oxides (1) is partly replaced by the nitrogen element.

Each insulating layer constituting the MIM element is preferably selected from the group consisting of SiO₂, SiN, Si₃N₄, Al₂O₃, SiON, HfO₂, HfSiON, Ta₂O₅, TiO₂, and SrTiO₃.

Si-based insulating films such as SiO₂, SiN, and SiON include those in which the oxygen element concentration and the nitrogen element concentration are each 1×10¹³ atoms/cm³ or more.

The insulator of the MIM element may include a plurality of insulating layers. In the case where the stacked structures STS are provided in a plurality of stages, the MIM elements in different stages may include a plurality of insulating layers. In these cases, the barrier height of the insulating layers may be different from each other.

The insulating layers include materials including impurity atoms or semiconductor/metal dots (quantum dots) forming defect levels.

### <Conductors>

The conductive lines functioning as the upper interconnect L1 and the lower interconnect L2 constituting the word line WL and the bit line BL are selected from e.g. the following materials:

One of, or a combination of a plurality of, e.g. W, WN, Al, Ti, V, Cr, Mn, Fe, Co, Ni, Cu, TiN, WSiₓ, TaSiₓ, PdSiₓ, ErSiₓ, YSiₓ, PtSiₓ, HfSiₓ, NiSiₓ, CoSiₓ, TiSiₓ, VSiₓ, CrSiₓ, MnSiₓ, and FeSiₓ.

The metal of the connecting electrode, the MIM element, the MIS (SMIS) element, and the element performing the transitioning operation is selected from e.g. the following materials:

Metallic elements in the form of simple substances, mixtures of a plurality of elements, silicides, oxides, and nitrides are exemplified.

Specifically, the metal is constituted by one of, or a combination of a plurality of, e.g. Pt, Au, Ag, TiAlN, SrRuO, Ru, RuN, Ir, Ti, V, Cr, Mn, Fe, Co, Ni, Cu, TiN, TaN, LaNiO, Al, PtIrOₓ, PtRhOₓ, Rh, TaAlN, SiTiOₓ, WSiₓ, TaSiₓ, PdSi_{X}, PtSiₓ, IrSiₓ, ErSiₓ, YSiₓ, HfSiₓ, NiSiₓ, CoSiₓ, TiSiₓ, VSiₓ, CrSiₓ, MnSiₓ, and FeSiₓ. The connecting electrode may simultaneously function as a barrier metal layer or a bonding layer.

The metal of the MIS (SMIS) element and the MIM element is constituted by one of, or a combination of a plurality of, e.g. the following materials.

(3-1) Single metallic element.

(3-2) Metal compounds as oxides, carbides, borides, nitrides, or silicides.

(3-3) TiN_{X}, TiC_{X}, TiBₓ, TiSiₓ, TaCₓ, TaBₓ, TaNₓ, TaSiₓ, WCₓ, WBₓ, W, WSiₓ, HfSiₓ, Hf, YSiₓ, and ErSiₓ.

The effective work functions of the two metal layers in the MIM element are preferably different from each other.

For instance, one of the two metal layers is constituted by one of, or a combination of a plurality of, e.g. ErSiₓ, HfSiₓ, YSiₓ, TaCₓ, TaNₓ, TiNₓ, TiC_{X}, TiBₓ, LaBₓ, La, and LaNₓ, having a low effective work function. Then, the other is preferably constituted by one of, or a combination of a plurality of, WNₓ, W, WBₓ, WCₓ, Pt, PtSiₓ, Pd, PdSiₓ, Ir, and IrSiₓ, having a high effective work function.

As described above, the nonvolatile memory device according to the embodiments can suppress the increase of the aspect ratio of the functional layer 100, and achieve processability improvement and characteristics uniformity.

The embodiments and the variations thereof have been described above. However, the embodiments are not limited to these examples. For instance, in the description of the above embodiments and variations, the first conductivity type is p-type and the second conductivity type is n-type. However, the embodiments can also be practiced in the case where the first conductivity type is n-type and the second conductivity type is p-type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a stacked structure including:
a plurality of first interconnects extending in a first direction;
a plurality of second interconnects spaced from the first interconnects and extending in a second direction crossing the first direction; and
a functional layer provided at each crossing position between the plurality of first interconnects and the plurality of second interconnects and having a transitioning function of transitioning between different resistance states and a rectifying function of rectifying current,
the functional layer including:
a metal layer;
an opposed layer; and
a semiconductor layer provided between the metal layer and the opposed layer and being in contact with each of the metal layer and the opposed layer.

2. The device according to claim 1, wherein
the semiconductor layer includes a first semiconductor region of a first conductivity type, and
the opposed layer includes a second semiconductor region of a second conductivity type.

3. The device according to claim 2, wherein the opposed layer includes a first intrinsic semiconductor region between the first semiconductor region and the second semiconductor region.

4. The device according to claim 2, wherein
the semiconductor layer includes a third semiconductor region of the second conductivity type, and
the third semiconductor region is provided between the first semiconductor region and the first interconnect.

5. The device according to claim 2, wherein
the opposed layer includes a fourth semiconductor region of the first conductivity type, and
the fourth semiconductor region is provided between the second semiconductor region and the second interconnect.

6. The device according to claim 5, wherein
the opposed layer includes a fifth semiconductor region of the second conductivity type, and
the fifth semiconductor region is provided between the fourth semiconductor region and the second interconnect.

7. The device according to claim 1, wherein
the semiconductor layer includes a first semiconductor region of a first conductivity type, and
the opposed layer includes:
a sixth semiconductor region of the first conductivity type; and
a first insulator region provided between the sixth semiconductor region and the first semiconductor region.

8. The device according to claim 1, wherein the opposed layer includes:
a first metal region;
a seventh semiconductor region; and
a second insulator region provided between the first metal region and the seventh semiconductor region.

9. The device according to claim 8, wherein the semiconductor layer includes a third intrinsic semiconductor region.

10. The device according to claim 1, wherein the opposed layer includes:
a second metal region;
a third metal region; and
a third insulator region provided between the second metal region and the third metal region.

11. The device according to claim 1, wherein the opposed layer includes:
an eighth semiconductor region;
a fourth metal region; and
a second intrinsic semiconductor region provided between the eighth semiconductor region and the fourth metal region.

12. The device according to claim 1, wherein the functional layer is applied with a set voltage when transitioning from one resistance state to one other resistance state, and is applied with a reset voltage when transitioning from the one other resistance state to the one resistance state, the reset voltage being identical in polarity to the set voltage and different in value from the set voltage.

13. The device according to claim 1, wherein the functional layer is applied with a set voltage when transitioning from one resistance state to one other resistance state, and is applied with a reset voltage when transitioning from the one other resistance state to the one resistance state, the reset voltage being different in polarity from the set voltage.

14. The device according to claim 1, wherein the resistance state of the functional layer transitions depending on presence or absence of a filament between the metal layer and the opposed layer.

15. The device according to claim 14, wherein the filament is a conduction path formed from metal atoms in the semiconductor layer.

16. The device according to claim 1, further comprising:
a plurality of third interconnects spaced from the first interconnects and the second interconnects and extending in the first direction; and
one other functional layer provided at each crossing position between the plurality of second interconnects and the plurality of third interconnects and having the transitioning function of transitioning between different resistance states and the rectifying function of rectifying current

17. The device according to claim 16, wherein two of the functional layers stacked between the first interconnects and the third interconnects have an identical stacking order of the metal layer, the semiconductor layer, and the opposed layer.

18. The device according to claim 16, wherein two of the functional layers stacked between the first interconnects and the third interconnects have a reverse stacking order of the metal layer, the semiconductor layer, and the opposed layer.

19. A nonvolatile memory device comprising:
a plurality of first interconnects extending in a first direction;
a plurality of second interconnects spaced from the first interconnects and extending in a second direction crossing the first direction;
a variable resistance element provided at each crossing position between the plurality of first interconnects and the plurality of second interconnects and transitioning between different resistance states; and
a rectifying element provided at the crossing position and rectifying current,
the variable resistance element including a semiconductor layer,
the rectifying element being in contact with the semiconductor layer.

20. A nonvolatile memory device comprising:
a plurality of first interconnects extending in a first direction;
a plurality of second interconnects spaced from the first interconnects and extending in a second direction crossing the first direction;
a variable resistance element including a semiconductor layer provided at each crossing position between the plurality of first interconnects and the plurality of second interconnects and transitioning between different resistance states; and
a rectifying element provided at the crossing position and rectifying current,
the semiconductor layer combining part of the rectifying element.
